(19) United States
(12) Patent Application Publication
(10) Pub. No.: US 2022/0177374 A1
(43) Pub. Date: Jun. 9, 2022

(54) A METHOD OF FABRICATING A CMC PART

(71) Applicants: SAFRAN CERAMICS, LE HAILLAN (FR); GENERAL ELECTRIC, CINCINNATI, OH (US)

(72) Inventors: Eric BOUILLON, MOISSY-CRAMAYEL (FR); Michael VERRILLI, CINCINNATI, OH (US); Eric PHILIPPE, MOISSY-CRAMAYEL (FR); Gildas GARNIER, MOISSY-CRAMAYEL (FR)

(21) Appl. No.: 17/601,270

(22) PCT Filed: Mar. 30, 2020
(86) PCT No.: PCT/EP2020/058929

§ 371 Date: Oct. 4, 2021

Related U.S. Application Data
(60) Provisional application No. 62/829,863, filed on Apr. 5, 2019.

(30) Foreign Application Priority Data
Oct. 7, 2019 (FR) FR1911064

(51) Int. Cl. C04B 35/565; C04B 35/80; C04B 35/628

(52) U.S. Cl. CPC C04B 35/565; C04B 35/80; C04B 35/62863; C04B 2235/5244; C04B 35/62873; C04B 2235/5252; C04B 35/62868

(57) ABSTRACT

A method of fabricating a CMC part, includes coating a plurality of tows with an interphase by transporting the tows through a treatment chamber in which a gas phase is injected, the tows being tensioned during their transport and the interphase being formed by vapor deposition from the injected gas phase; forming a fiber preform by performing three-dimensional weaving using the tows coated with the interphase; and forming a consolidated fiber preform by treating the fiber preform by chemical vapor infiltration to form a consolidation phase on the interphase, the consolidation phase comprising silicon carbide and having a Young's modulus greater than or equal to 350 GPa.

The invention relates to ceramic matrix composite (CMC) parts and to methods for fabricating such parts.

A field of application of the invention is making parts that are to be exposed to high temperatures in service, specifically in the fields of aviation and space, in particular parts for the hot portions of aviation turbine engines, it being understood that the invention can be applied to other fields, e.g. to the field of industrial gas turbines.

### BACKGROUND OF THE INVENTION

CMC materials present good thermostructural properties, i.e. good mechanical properties that make them suitable for constituting structural parts, together with the ability to retain those properties at high temperatures. CMC materials comprise of fiber reinforcement made up of tows of ceramic or carbon materials present within a ceramic matrix. The use of CMC materials instead of metal materials for parts that are exposed to high temperatures in service is desirable, particularly since such materials present density that is considerably less than the density of the metal materials they replace.

It is in particular known to fabricate a CMC part by a technique wherein plies of fibers coated with an interphase are impregnated by a resin mixture and then laid up in the desired orientation to obtain a preform of the part to be obtained. After formation of the preform, the resin is pyrolyzed and then densification of the preform is carried out by infiltration with molten silicon or molten silicon alloy to form a ceramic matrix. The inventors have observed that the thus obtained product may not be entirely satisfactory since layers of matrix between each plies, can lead to temperature creep weakness, due to the presence of free silicon. In this type of product, incorporated matrix phases, characterized by a low creep resistance, as free silicon in the matrix obtained by melt-infiltration, can lead to fibers overloading exceeding their creep resistance and thus decreasing the time to rupture.

It is thus desirable to provide CMC parts having improved mechanical properties, and in particular better creep resistance, at high temperature.

### OBJECT AND SUMMARY OF THE INVENTION

The present invention provides a method of fabricating a CMC part, the method comprising at least:
coating a plurality of tows with an interphase by transporting the tows through a treatment chamber in which a gas phase is injected, the tows being tensioned during their transport and the interphase being formed by vapor deposition from the injected gas phase;
forming a fiber preform through three-dimensional weaving using the tows coated with the interphase; and
forming a consolidated fiber preform by treating the fiber preform by chemical vapor infiltration to form a consolidation phase on the interphase, the consolidation phase comprising silicon carbide and having a Young's modulus greater than or equal to 350 GPa.

Unless the contrary is specified, the Young's modulus of the consolidation phase is measured at 20° C.

The combination of the reinforcement obtained by three-dimensional weaving and of the CVI (“Chemical Vapor Infiltration”) silicon carbide consolidation phase with a high modulus leads to an interconnected and rigid 3D network without free silicon, which provides high creep resistance at high temperature to the material. The inventors have also observed that forming the interphase by vapor deposition on a tow transported under tension provides an individual coating around each fiber of the tow, as well as a good intra-tow filing, due to a beneficial effect of fibers spacing in the tow. The filing of the tow is thus more homogeneous in comparison with forming the interphase by CVI on the fibers of an already woven preform in which the gas permeability of the tows is limited. In the invention, the formed interphase notably provides an improved fiber to fiber loading transfer and also avoids the risk of glass linkage and rupture of bundles of adjacent fibers during oxidative exposure. The solution proposed by the present invention thus provides a CMC part having improved mechanical properties at high temperature.

In an embodiment, the consolidation phase has a Young's modulus greater than or equal to 375 GPa, for example greater than or equal to 400 GPa.

This feature advantageously further improves the creep resistance of the CMC part.

In an embodiment, the residual volume porosity of the consolidated fiber preform lies in the range 25% to 45%, for example in the range 30% to 35%.

The inventors have observed that this feature advantageously optimizes the creep resistance at high temperature.

In an embodiment, the method further comprises densifying the consolidated fiber preform by forming a silicon carbide matrix phase on the consolidation phase by infiltration with a molten composition comprising silicon, carbon and/or ceramic particles being present in the porosity of the consolidated preform before infiltration.

This feature advantageously leads to a ceramic matrix having a low porosity, thus reducing stress concentrations under mechanical loading and improving matrix resistance to cracking.

In an embodiment, the interphase is formed by at least one layer of the following materials: boron nitride, boron nitride doped with silicon, pyrolytic carbon or boron-doped carbon. In an example, the interphase may be covered by a protective layer of at least one of the following materials: silicon nitride or silicon carbide.

In an embodiment, the tows comprises silicon carbide fibers presenting an oxygen content that is less than or equal to 1% in atomic percentage.

The present invention also provides a CMC part comprising at least:
a 3D-woven fiber reinforcement comprising a plurality of tows, the tows having a plurality of fibers that are individually coated with an interphase; and
a consolidation phase densifying the fiber reinforcement and located on the interphase, the consolidation phase comprising silicon carbide and having a Young's modulus greater than or equal to 350 GPa, the consolidation phase not containing free silicon.

This CMC part may be obtained by carrying out the above described method.

In an embodiment, the consolidation phase has a Young's modulus greater than or equal to 375 GPa, for example greater than or equal to 400 GPa.

As above indicated, this feature advantageously further improves the creep resistance of the CMC part.

In an embodiment, the volume fraction of the consolidation phase lies in the range 5% to 30%, for example in the range 10% to 30%.

This feature advantageously optimizes the creep resistance at high temperature.

In an embodiment, the part further comprises a silicon carbide matrix phase located on the consolidation phase, said silicon carbide matrix phase having a residual volume porosity less than or equal to 8%.

As above indicated, this feature advantageously reduces stress concentrations under mechanical loading and improves matrix resistance to cracking.

In an embodiment, the interphase is formed by at least one layer of the following materials: boron nitride, boron nitride doped with silicon, pyrolytic carbon or boron-doped carbon.

In an embodiment, the tows comprises silicon carbide fibers presenting an oxygen content that is less than or equal to 1% in atomic percentage.

By way of example, the part may be a turbine engine part. By way of example, the part may be a turbine ring or a turbine ring sector, a blade, a vane, a combustor liner, or a nozzle.

### BRIEF DESCRIPTION OF THE DRAWINGS

Other characteristics and advantages of the invention appear from the following description, which is given in non-limiting manner and with reference to the accompanying drawings, in which:

FIG. 1 is a flowchart of an example of a method according to the invention; and

FIG. 2 generally illustrates a device for forming the interphase on the tows while they are transported through a treatment chamber that may be used in the invention.

### DETAILED DESCRIPTION OF EMBODIMENTS

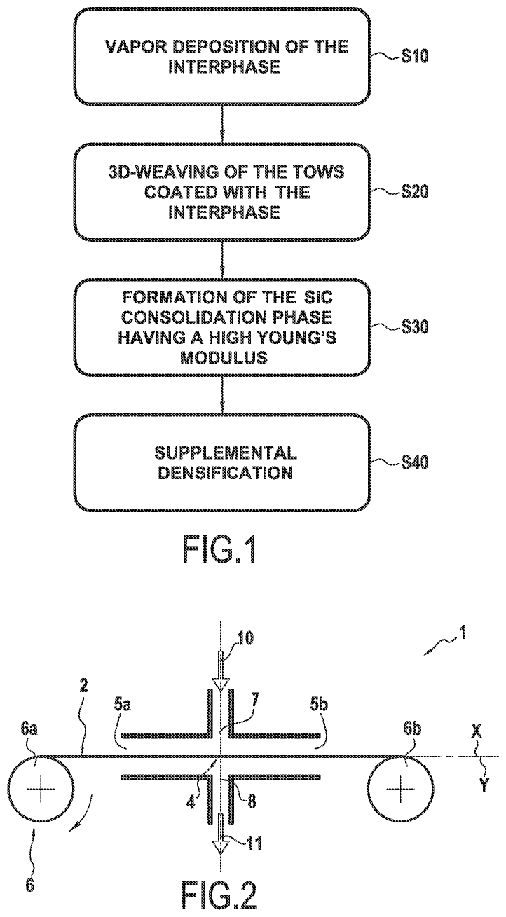

The method starts by coating the tows with an interphase by performing vapor deposition (step S10 in FIG. 1).

The tows may comprise ceramic fibers, e.g., nitride, or carbide fibers, e.g. silicon carbide fibers. In another variant, the tows may comprise carbon fibers. In an example, the tows comprises silicon carbide fibers presenting an oxygen content that is less than or equal to 1% in atomic percentage. Examples of such tows are supplied under the name “Hi-Nicalon-S” by the NGS company, under the name “Tyranno SA3” by the supplier UBE, or under the name “Sylramic i-BN” by the supplier COI Ceramics. One tow comprises a plurality of fibers, for example at least one hundred of fibers, typically 500 fibers.

The interphase serves to slow down rupture of the fibers of the tows by cracks that start initially within the matrix. By way of example, the embrittlement-release interphase may comprise a material of lamellar structure that, on a crack reaching the interphase, is capable of dissipating the cracking energy by localized un-bonding at atomic scale so that the crack is deflected within the interphase. The interphase is a coating that may comprise one layer or multiple layers. The interphase may include one or more layers of: boron nitride BN, boron nitride doped with silicon BN(Si) (with a mass content of silicon lying in the range 5% to 40%, the remainder being boron nitride), pyrolytic carbon PyC or boron-doped carbon boron carbide (with an atom content of boron lying in the range 5% to 20%, the remainder being carbon). The thickness of the interphase may be greater than or equal to 10 nanometers (nm), and for example may lie in the range 10 nm to 1000 nm. In known manner, it may be preferable to perform surface treatment on the fibers of the tows prior to forming the interphase in order to eliminate the sizing and a surface layer of oxide such as silica SiO₂ present on the fibers.

Methods and devices for coating the tows by an interphase formed by vapor deposition while these tows are transported under tension through a treatment chamber are known. Concerning this aspect, it is for example possible to refer to document FR 3 044 022, the content of which is incorporated by reference in its entirety.

A brief description of an example of a suitable device 1 for forming the interphase on the tows 2 is hereunder provided with reference to FIG. 2.

The device 1 includes a treatment chamber 4 through which a plurality of tows 2 for coating are transported by being driven by a conveyor system 6, here comprising first 6a and second 6b sets of pulleys. Each set 6a or 6b comprises one or a plurality of pulley(s). During the coating, the tows 2 are transported by the conveyor system 6 from the inlet end 5a to the outlet end 5b. The conveyor system 6 is configured to transport the tows 2 through the treatment chamber 4 along a conveyor axis Y. In the example shown, the conveyor axis Y is parallel to the longitudinal axis X of the device 1. The tows 2 are tensioned between the pulleys 6a and 6b and they are tensioned between the inlet and outlet ends 5a and 5b. Because of the tension applied, the fibers of the tows 2 spread which leads to a more homogeneous filling of the tows 2 and individual coating of the fibers. The tows 2 may be continuously transported through the treatment chamber 4 during the coating with the interphase. In this case, the tows 2 do not stop while they are transported through the treatment chamber 4.

The tows 2 that are to be coated by the interphase may not be interlinked (in particular the tows 2 are not woven, knitted, or braided together). The tows 2 may not have been subjected to any textile operation and they may not form a fiber structure during the coating with the interphase.

The Interphase is obtained by injecting a gas phase 10 into the treatment chamber 4 through an inlet orifice 7 to form the interphase on the tows 2. The interphase may be formed by chemical vapor deposition (CVD). The interphase may be formed in contact with the fibers of the tows. Any gas phase that has not reacted, together with by-products of the reaction are pumped out via an outlet orifice 8 (arrow 11). The device 1 also comprises a heater system configured to heat the treatment chamber 4 in order to perform vapor deposition. The heater system may heat the treatment chamber 4 by induction or radiant heating. When a PyC interphase is to be formed, the gas phase 10 may comprise one or more gaseous hydrocarbons, e.g. selected from methane, ethane, propane, and butane. In a variant, the gas phase 10 may include a gaseous precursor for a ceramic material, such as a combination of boron trichloride BCl₃ and ammonia NH₃. In order to make a given interphase, selecting the precursor(s) to be used together with the pressure and temperature conditions to be imposed in the treatment chamber 4 form part of the general knowledge of the person skilled in the art.

Multilayer interphase can be made by placing a plurality of units of this type in series each including a device for injecting a gas phase and a device for removing the residual gas phase.

Once the tows 2 have been coated with the interphase, the method continues by performing a three-dimensional weaving of the coated tows to form a fiber preform of the part to be obtained (step S20 in FIG. 1).

The fiber preform is to form the fiber reinforcement of the part to be obtained. The fiber preform is obtained by three-dimensional weaving between a plurality of layers of warp tows and a plurality of layers of weft tows. The fiber preform may be made as a single piece by three-dimensional weaving. The three-dimensional weaving may be performed using an “interlock” weave, i.e. a weave in which each layer of weft tows interlinks a plurality of layers of warp tows, with all of the tows in the same weft column having the same movement in the weave plane. The roles between warp and weft can be inverted, and such an inversion should be considered as also being covered by the claims. Naturally, it would not go beyond the ambit of the invention to use other types of 3D-weave. Various suitable weaving techniques are described in document WO 2006/136755, the content of which is incorporated by reference in its entirety.

In a known manner, it may be preferable to treat the coated tows before weaving with a sizing composition including a linear polysiloxane, to avoid any risk of damaging the interphase during the weaving. An example of such a sizing composition is disclosed in document US 2017/073854, the content of which is incorporated by reference in its entirety. Another solution to avoid any risk of damaging of the interphase is to form the preform using a weaving loom having elements that come into contact with the tows that are made of molybdenum. This type of weaving loom is disclosed in document FR 3045679, the content of which is incorporated by reference in its entirety.

After formation of the 3D-woven preform, a consolidation phase comprising silicon carbide is formed by CVI in the pores of the fiber preform and on the interphase (step S30 in FIG. 1). The consolidation phase may be formed in contact with the interphase. The consolidation phase obtained by CVI does not contain free silicon and has a high Young's modulus, greater than or equal to 350 GPa. The Young's modulus of the consolidation phase may for example lie in the range 350 GPa to 450 GPa, for example in the range 350 GPa to 420 GPa. As above mentioned, this consolidation phase provides the part with the desired creep resistance at high temperature. The consolidation phase comprises silicon carbide, optionally doped with a self-healing material such as boron B or boron carbide B₄C.

The thickness of the consolidation phase may be greater than or equal to 500 nm, e.g. lying in the range 1 micrometer (μm) to 30 μm. The thickness of the consolidation phase is sufficient to consolidate the fiber preform, i.e. to link together the tows of the preform sufficiently to enable the preform to be handled while conserving its shape without assistance from support tooling.

After formation of the consolidation phase and before starting the optional supplemental densification (step S40 in FIG. 1), the residual volume porosity of the consolidated fiber preform may be less than or equal to 45%, for example may lie in the range 30% to 35%. The volume fraction of the consolidation phase in the consolidated fiber preform (or in the CMC part) may be greater than or equal to 5%. In an example, this volume fraction of the consolidation phase lies in the range 10% to 30%.

After formation of the consolidation phase, a supplemental densification step may be carried out to terminate densification of the preform (step S40). The ceramic matrix phase formed during the supplemental densification step S40 is formed on the consolidation phase and may be in contact with the consolidation phase.

In an embodiment, this supplemental densification step corresponds to a densification by slurry-cast infiltration plus a melt-infiltration technique. In this case, a ceramic and/or carbon powder may be introduced into the pores of the consolidated fiber preform. To do this, the consolidated preform may be impregnated with a slurry containing the powder in suspension in a liquid medium, e.g. water. The powder may be retained in the preform by filtering, possibly with the assistance of suction or pressure. It is preferable to use a powder made up of particles having a mean size (D50) that is less than or equal to 5 μm, or even less than or equal to 2 μm. Before infiltration with the molten composition, the powder is present in the pores of the consolidated fiber preform. The powder may comprise of silicon carbide particles. In addition or in replacement to silicon carbide particles, particles of some other material, e.g. such as carbon, boron carbide, silicon boride, silicon nitride, may be present in the pores of the fiber preform.

Thereafter, the consolidated fiber preform comprising the particles is infiltrated by a molten composition comprising silicon. This composition may correspond to molten silicon on its own or to an alloy of silicon in the molten state that also contains one or more other elements such as titanium, molybdenum, boron, iron, or niobium. The content by weight of silicon in the molten composition may be greater than or equal to 50%, for example greater than equal to 75%, for example greater than or equal to 90%.

Naturally, it would not go beyond the ambit of the invention to use other types of techniques for the supplemental densification step S40. For example, the supplemental densification step may be carried out in a known manner by CVI or by a Polymer Infiltration and Pyrolysis (PIP) technique. In an example, the CVI technique used for forming the consolidation phase may be continued so as to completely densify the fiber preform. In this case, all the ceramic matrix of the CMC part may be obtained by CVI.

The term “lying in the range . . . to . . . ” should be understood as including the bounds.

1. A method of fabricating a CMC part, the method comprising:
coating a plurality of tows with an interphase by transporting the tows through a treatment chamber in which a gas phase is injected, the tows being tensioned during their transport and the interphase being formed by vapor deposition from the injected gas phase;
forming a fiber preform by performing three-dimensional weaving using the tows coated with the interphase; and
forming a consolidated fiber preform by treating the fiber preform by chemical vapor infiltration to form a consolidation phase on the interphase, the consolidation phase comprising silicon carbide and having a Young's modulus greater than or equal to 350 GPa, a volume fraction of the consolidation phase lying in the range from 5% to 30%.

2. The method according to claim 1, wherein the consolidation phase has a Young's modulus greater than or equal to 375 GPa.

3. The method according to claim 1, wherein the residual volume porosity of the consolidated fiber preform lies in the range 25% to 45%.

4. The method according to claim 1, the method further comprising densifying the consolidated fiber preform by forming a silicon carbide matrix phase on the consolidation phase by infiltration with a molten composition comprising silicon, and wherein carbon and/or ceramic particles are present in a porosity of the consolidated preform before infiltration.

5. The method according to claim 1, wherein the interphase is formed by at least one layer of the following materials: boron nitride, boron nitride doped with silicon, pyrolytic carbon or boron-doped carbon.

6. The method according to claim 1, wherein the tows comprises silicon carbide fibers presenting an oxygen content that is less than or equal to 1% in atomic percentage.

7. A CMC part comprising:
a 3D-woven fiber reinforcement comprising a plurality of tows, the tows having a plurality of fibers that are individually coated with an interphase; and
a consolidation phase densifying the fiber reinforcement and located on the interphase, the consolidation phase comprising silicon carbide and having a Young's modulus greater than or equal to 350 GPa, the consolidation phase not containing free silicon, a volume fraction of the consolidation Phase lying in the range 5% to 30%.

8. The CMC part according to claim 7, wherein the consolidation phase has a Young's modulus greater than or equal to 375 GPa.

9. (canceled)

10. The CMC part according to claim 7, further comprising a silicon carbide matrix phase located on the consolidation phase, said silicon carbide matrix phase having a residual volume porosity less than or equal to 8%.

11. The CMC part according to claim 7, wherein the interphase is formed by at least one layer of the following materials: boron nitride, boron nitride doped with silicon, pyrolytic carbon or boron-doped carbon.

12. The CMC part according to claim 7, wherein the tows comprises silicon carbide fibers presenting an oxygen content that is less than or equal to 1% in atomic percentage.

13. The CMC part according to claim 8, wherein the interphase is formed by at least one layer of the following materials: boron nitride, boron nitride doped with silicon, pyrolytic carbon or boron-doped carbon.

14. The CMC part according to claim 10, wherein the interphase is formed by at least one layer of the following materials: boron nitride, boron nitride doped with silicon, pyrolytic carbon or boron-doped carbon.

15. The CMC part according to claim 8, wherein the tows comprises silicon carbide fibers presenting an oxygen content that is less than or equal to 1% in atomic percentage.

16. The CMC part according to claim 10, wherein the tows comprises silicon carbide fibers presenting an oxygen content that is less than or equal to 1% in atomic percentage.

17. The CMC part according to claim 11, wherein the tows comprises silicon carbide fibers presenting an oxygen content that is less than or equal to 1% in atomic percentage.
